(19) United States
(12) Patent Application Publication
(10) Pub. No.: US 2023/0207428 A1
(43) Pub. Date: Jun. 29, 2023

(54) INTEGRATED CIRCUIT DIE FOR EFFICIENT INCORPORATION IN A DIE STACK

(71) Applicant: Intel Corporation, Santa Clara, CA (US)

(72) Inventors: Surhud Khare, Buffalo, NY (US); Shigeki Tomishima, Portland, OR (US); Debendra Mallik, Chandler, AZ (US)

(73) Assignee: Intel Corporation, Santa Clara, CA (US)

(21) Appl. No.: 17/560,915

(22) Filed: Dec. 23, 2021

(51) Int. Cl. H01L 23/48; H01L 23/528; H01L 21/768; H01L 25/065

(52) U.S. Cl. CPC H01L 23/481; H01L 21/76898; H01L 23/528; H01L 25/0657

(57) ABSTRACT

Techniques and mechanisms for incorporating an integrated circuit (IC) die into a die stack. In an embodiment, the die comprises multiple interconnects extending vertically through the die. The multiple interconnects comprise first interconnects which participate in communications via a first channel, second interconnects which participate in communications via a second channel, and third interconnects which are locally insulated from any transmitter or receiver circuitry of the die. Along a direction within a horizontal plane, the third interconnects are in an alternating arrangement with the first interconnects and the second interconnects, wherein the first interconnects and the second interconnects are on opposite sides of a line which is orthogonal to the direction. In another embodiment, along the direction, the first interconnects are successively arranged to correspond to successively greater levels of bit significance, and the second interconnects are successively arranged to correspond to successively lesser levels of bit significance.

### BACKGROUND

### 1. Technical Field

This disclosure generally relates to integrated circuit dies and more particularly, but not exclusively, to interconnect structures which facilitate the stacking of dies with each other.

### 2. Background Art

Various arrangements for memory dies in a memory system have been proposed. In a traditional random access memory (or other) system, memory dies communicate data through multi-drop data buses, and receive commands and addresses through command and addresses buses. More recently, bidirectional or unidirectional point-to-point interconnects have been proposed.

In some systems, dies (also called chips) are stacked one on top of another. The dies may be all of the same type, or some of the dies may be different than others. In many traditional memory architectures, a stack of memory dies (e.g., flash or DRAM) are supported by a module substrate. Usually, such a stack further includes a die with a memory controller, a processor (with or without a memory controller) a voltage regulator (VR) circuit and/or the like.

In-Package Memory (IPM) integration is becoming increasingly important to satisfy growing bandwidth demands for the performance of various compute-capable devices. IPM designs, whether they leverage custom or commodity memory technologies, tend to be cost sensitive, and thus are frequently limited in their ability to efficiently integrate higher bandwidth and/or capacity in an affordable manner. Accordingly, there is expected to be an increasing premium placed on improvements to solutions which facilitate the integration of memory in a die stack.

### BRIEF DESCRIPTION OF THE DRAWINGS

The various embodiments of the present invention are illustrated by way of example, and not by way of limitation, in the figures of the accompanying drawings and in which:

FIG. 1 shows a side view diagram illustrating features of a device comprising an integrated circuit (IC) die stack according to an embodiment.

FIG. 2 shows a flow diagram illustrating features of a method to provide structures of an IC die according to an embodiment.

FIGS. 3A, 3B show a top view diagram and a layout diagram each illustrating respective features of an IC die to facilitate stacking with one or more other dies according to a corresponding embodiment.

FIG. 4 shows an exploded view diagram illustrating features of a device comprising an IC die stack according to an embodiment.

FIGS. 5A, 5B show a layout diagrams each illustrating respective features of an IC die according to a corresponding embodiment.

FIG. 6 shows an exploded view diagram illustrating features of a device comprising an IC die stack according to an embodiment.

FIG. 7 shows an exploded view diagram illustrating features of a device comprising an IC die stack according to an embodiment.

FIG. 8 is a functional block diagram illustrating a computing device in accordance with one embodiment.

FIG. 9 is a functional block diagram illustrating an exemplary computer system, in accordance with one embodiment.

### DETAILED DESCRIPTION

Embodiments discussed herein variously provide techniques and mechanisms for incorporating an integrated circuit (IC) die into a die stack. In the following description, numerous details are discussed to provide a more thorough explanation of the embodiments of the present disclosure. It will be apparent to one skilled in the art, however, that embodiments of the present disclosure may be practiced without these specific details. In other instances, well-known structures and devices are shown in block diagram form, rather than in detail, in order to avoid obscuring embodiments of the present disclosure.

Note that in the corresponding drawings of the embodiments, signals are represented with lines. Some lines may be thicker, to indicate a greater number of constituent signal paths, and/or have arrows at one or more ends, to indicate a direction of information flow. Such indications are not intended to be limiting. Rather, the lines are used in connection with one or more exemplary embodiments to facilitate easier understanding of a circuit or a logical unit. Any represented signal, as dictated by design needs or preferences, may actually comprise one or more signals that may travel in either direction and may be implemented with any suitable type of signal scheme.

Throughout the specification, and in the claims, the term “connected” means a direct connection, such as electrical, mechanical, or magnetic connection between the things that are connected, without any intermediary devices. The term “coupled” means a direct or indirect connection, such as a direct electrical, mechanical, or magnetic connection between the things that are connected or an indirect connection, through one or more passive or active intermediary devices. The term “circuit” or “module” may refer to one or more passive and/or active components that are arranged to cooperate with one another to provide a desired function. The term “signal” may refer to at least one current signal, voltage signal, magnetic signal, or data/clock signal. The meaning of “a,” “an,” and “the” include plural references. The meaning of “in” includes “in” and “on.”

The term “device” may generally refer to an apparatus according to the context of the usage of that term. For example, a device may refer to a stack of layers or structures, a single structure or layer, a connection of various structures having active and/or passive elements, etc. Generally, a device is a three-dimensional structure with a plane along the x-y direction and a height along the z direction of an x-y-z Cartesian coordinate system. The plane of the device may also be the plane of an apparatus which comprises the device.

The term “scaling” generally refers to converting a design (schematic and layout) from one process technology to another process technology and subsequently being reduced in layout area. The term “scaling” generally also refers to downsizing layout and devices within the same technology node. The term “scaling” may also refer to adjusting (e.g., slowing down or speeding up - i.e. scaling down, or scaling up respectively) of a signal frequency relative to another parameter, for example, power supply level.

The terms “substantially,” “close,” “approximately,” “near,” and “about,” generally refer to being within +/-10% of a target value. For example, unless otherwise specified in the explicit context of their use, the terms “substantially equal,” “about equal” and “approximately equal” mean that there is no more than incidental variation between among things so described. In the art, such variation is typically no more than +/-10% of a predetermined target value.

It is to be understood that the terms so used are interchangeable under appropriate circumstances such that the embodiments of the invention described herein are, for example, capable of operation in other orientations than those illustrated or otherwise described herein.

Unless otherwise specified the use of the ordinal adjectives “first,” “second,” and “third,” etc., to describe a common object, merely indicate that different instances of like objects are being referred to and are not intended to imply that the objects so described must be in a given sequence, either temporally, spatially, in ranking or in any other manner.

The terms “left,” “right,” “front,” “back,” “top,” “bottom,” “over,” “under,” and the like in the description and in the claims, if any, are used for descriptive purposes and not necessarily for describing permanent relative positions. For example, the terms “over,” “under,” “front side,” “back side,” “top,” “bottom,” “over,” “under,” and “on” as used herein refer to a relative position of one component, structure, or material with respect to other referenced components, structures or materials within a device, where such physical relationships are noteworthy. These terms are employed herein for descriptive purposes only and predominantly within the context of a device z-axis and therefore may be relative to an orientation of a device. Hence, a first material “over” a second material in the context of a figure provided herein may also be “under” the second material if the device is oriented upside-down relative to the context of the figure provided. In the context of materials, one material disposed over or under another may be directly in contact or may have one or more intervening materials. Moreover, one material disposed between two materials may be directly in contact with the two layers or may have one or more interveninhg layers. In contrast, a first material “on” a second material is in direct contact with that second material. Similar distinctions are to be made in the context of component assemblies.

The term “between” may be employed in the context of the z-axis, x-axis or y-axis of a device. A material that is between two other materials may be in contact with one or both of those materials, or it may be separated from both of the other two materials by one or more intervening materials. A material “between” two other materials may therefore be in contact with either of the other two materials, or it may be coupled to the other two materials through an intervening material. A device that is between two other devices may be directly connected to one or both of those devices, or it may be separated from both of the other two devices by one or more intervening devices.

As used throughout this description, and in the claims, a list of items joined by the term “at least one of” or “one or more of” can mean any combination of the listed terms. For example, the phrase “at least one of A, B or C” can mean A; B; C; A and B; A and C; B and C; or A, B and C. It is pointed out that those elements of a figure having the same reference numbers (or names) as the elements of any other figure can operate or function in any manner similar to that described, but are not limited to such.

In addition, the various elements of combinatorial logic and sequential logic discussed in the present disclosure may pertain both to physical structures (such as AND gates, OR gates, or XOR gates), or to synthesized or otherwise optimized collections of devices implementing the logical structures that are Boolean equivalents of the logic under discussion.

The technologies described herein may be implemented in one or more electronic devices. Non-limiting examples of electronic devices that may utilize the technologies described herein include any kind of mobile device and/or stationary device, such as cameras, cell phones, computer terminals, desktop computers, electronic readers, facsimile machines, kiosks, laptop computers, netbook computers, notebook computers, internet devices, payment terminals, personal digital assistants, media players and/or recorders, servers (e.g., blade server, rack mount server, combinations thereof, etc.), set-top boxes, smart phones, tablet personal computers, ultra-mobile personal computers, wired telephones, combinations thereof, and the like. More generally, the technologies described herein may be employed in any of a variety of electronic devices which include, or facilitate coupling to operate with, an IC die.

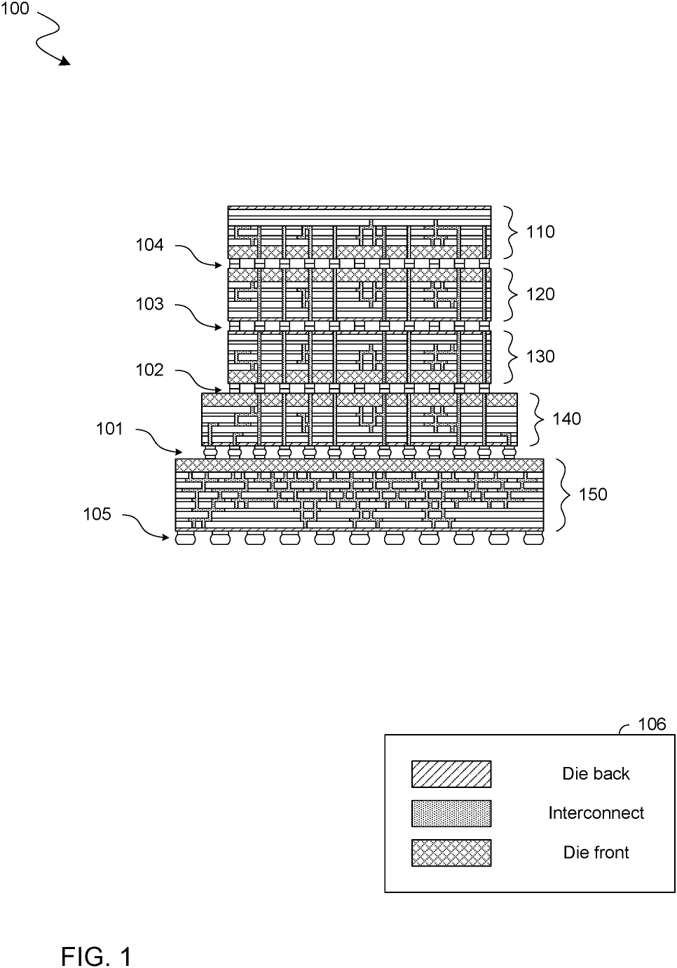

FIG. 1 illustrates features of a device 100 comprising a stack of IC dies (or “die stack”) according to an embodiment. The elements of FIG. 1 and the following figures are presented for illustration, and are not drawn to scale. Device 100 illustrates one example of an embodiment wherein an IC die comprises first interconnects which are to variously participate in communications via different channels, and second interconnects which — along a direction in a horizontal plane — are in an alternating arrangement with the first interconnects. The arrangement of the interconnects (e.g., including their arrangement at a horizontal plane within the IC die) facilitates efficient coupling of the IC die to another IC die.

As shown in FIG. 1, device 100 comprises a substrate 150, a host die 140, and one or more other dies — for example, including DRAM (and/or other memory) dies — which are coupled to substrate 150 in a vertically stacked arrangement with host die 140. In the example embodiment shown, the one or more other dies comprise IC dies 110, 120, 130. Although device 100 is shown as including a stack of four dies (e.g., including three memory dies), some embodiments, which are not limited to any particular number of dies in a stack, instead include a greater or smaller number of memory dies.

In some embodiments, dies of a die stack each include a respective one or more hardware interfaces - e.g., each comprising respective metal pins, pads, microbumps, balls and/or other conductive contacts - which are each for coupling a given die with a respective other die of the stack. By way of illustration and not limitation, device 100 comprises an interface region 101 where a hardware interface of substrate 150 (e.g., an interposer, a package substrate, a circuit board, or the like) is flip-chip connected, hybrid bonded or otherwise coupled to a bottom-side hardware interface of host die 140. Furthermore, device 100 comprises an interface region 102 where a top-side hardware interface of host die 140 is coupled to a bottom-side hardware interface of die 130 - e.g., wherein a top-side hardware interface of die 130 is coupled to a bottom-side hardware interface of die 120 at another interface region 103. Further still, device 100 comprises an interface region 104 where a top-side hardware interface of die 120 is coupled to a bottom-side hardware interface of die 110. In one such embodiment, substrate 150 comprises a bottom-side hardware interface 105 which (for example) comprises solder balls to provide electrical connectivity between substrate 150 and another substrate, such as that of a main board, a printed circuit board (PCB) motherboard, or the like.

Although some embodiments are not limited in this regard, host die 140 comprises a system on chip (SoC) or other suitable host logic which, for example, is to control access to memory resources of the one or more other dies. For example, host die 140 includes a memory controller (not shown) for accessing a stack of memory dies. Host die 140 is shown as being coupled below dies 110, 120, 130, although some embodiments are not limited in this regard. For example, in other embodiments, host die 140 is located adjacent to a memory stack which includes dies 110, 120, 130, and thus is coupled in a side-by-side arrangement with the memory stack. In some embodiments, device 100 omits substrate 150 and/or host die 140, for example.

Dies of the die stack - e.g., including at least two of dies 110, 120, 130 - each comprise respective interconnects which facilitate a communication of data bits and/or address bits between said dies. For example, in some embodiments, the die stack comprises memory dies (with the possible exception of a top, or outermost, memory die layer, such as die 110 in this illustration) which each include a respective plurality of through silicon vias (TSVs) to provide paths through respective silicon substrates of said memory dies. In various embodiments, device 100 comprises circuit structures to enable such memory dies each to drive a respective subset of the memory interconnects - e.g., where the interconnects accommodate variety as to how IC dies are stacked relative to each other.

Certain features of various embodiments are described herein with reference to an IC die which comprises multiple interconnects that include pass-through interconnects, as well as other interconnects which are variously coupled to participate in communications with transmitter circuitry and/or receiver circuitry of the IC die.

In this particular context of an interconnect which extends through an IC die, “pass-through” refers herein to the characteristic of the interconnect being electrically insulated — at least locally at that IC die — from any transmitter circuit and/or receiver circuit of the IC die. More particularly, any electrical connection of such a pass-through (or “locally insulated”) interconnect to a transmit driver circuit or receiver circuit of the same IC die is only via a conductive path which includes one or more conductors external to that IC die. In various embodiments, pass-through interconnects are to be coupled to transmitter circuitry or receiver circuitry of another IC die in a die stack - e.g., to facilitate a doubling (or other increasing) of memory access bandwidth along the die stack.

Some embodiments variously accommodate the coupling of dies with each other in one of a face-to-face configuration, a back-to-back configuration, or a face-to-back configuration. In the particular context of a given side of an IC die, “face” (or “front”) refers to a side which is formed by the front end of line (FEOL) of that die, or which is otherwise closer to said FEOL than is the back end of line (BEOL) of the die. Similarly, in this context, “back” refers herein to a side of an IC die which is formed by BEOL of that die, or which is otherwise closer to said BEOL than is the FEOL of the die. Legend 106 shows respective fronts and respective backs of dies 110, 120, 130, 140, as well as of substrate 150.

In various embodiments, a given two interconnects of an IC die form a swizzle circuit. In this particular context, “swizzle” refers to the characteristic of two circuit structures (in this case, two interconnects) variously extending along a given dimension through two planes which are each orthogonal to said dimension, wherein — between the two planes — the two interconnects switch (or “swizzle”) between having a first order in one of the planes, to having a second, different order — e.g., an opposite order— in the other of the planes. For example, the first order and the second order are each with reference to parallel lines each in a different respective one of the two planes - e.g., with reference to where the two circuit structures are variously located along each of two lines.

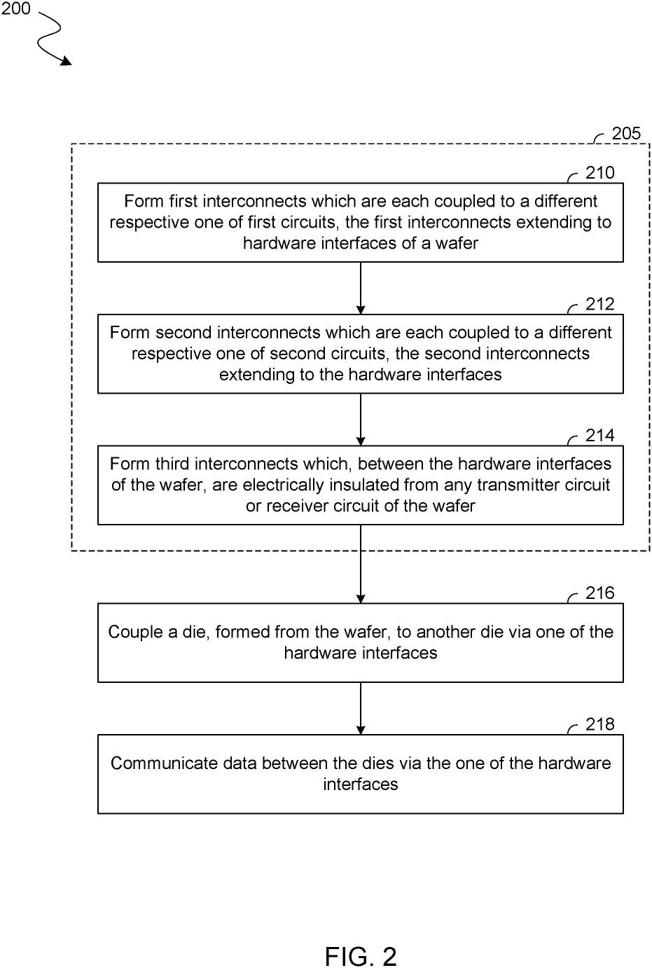

FIG. 2 illustrates features of a method 200 to provide structures of an IC die according to an embodiment. Operations such as those of method 200 are performed, for example, to provide and/or operate some or all structures of device 100 - e.g., wherein method 200 is to provide one of dies 110, 120, 130.

As shown in FIG. 2, method 200 comprises operations 205 to fabricate structures of a wafer which, for example, is subsequently diced to form an IC die. For example, operations 205 comprise (at 210) forming first interconnects which each extend to both of two hardware interfaces of the wafer. The two hardware interfaces, which are on opposite respective sides of the wafer, are each to facilitate coupling of the subsequently formed IC die with a different respective IC die. During or after the forming at 210, the wafer comprises first circuits which, as a result of method 200, are each coupled to a different respective one of the first circuits. For example, the first circuits each comprise a respective transmit driver circuit (or alternatively, each comprise a respective receiver circuit) - which provides functionality to participate in first communications with one or more other IC die via a first channel.

In various embodiments, the forming at 210 includes one or more operations which (for example) are adapted from conventional masking, lithographic etch, metallization, and/or other fabrication techniques - e.g., the operations to form interconnect structures in a back end of line (BEOL) of the die and/or interconnect structures in a front end of line (FEOL) of the die. Such conventional fabrication techniques are not limiting on various embodiments, and are not detailed herein to avoid obscuring features of such embodiments.

Operations 205 further comprise (at 212) forming second interconnects which each extend to both of the two hardware interfaces. During or after the forming at 212, the wafer further comprises second circuits which, as a result of method 200, are each coupled to a different respective one of the second circuits. For example, the second circuits each comprise a respective transmit driver circuit (or alternatively, each comprise a respective receiver circuit) -which provides functionality to participate in second communications with one or more other IC die via a second channel. In various embodiments, the forming at 212 is performed concurrently with, and/or otherwise includes features of, the forming at 210.

Operations 205 further comprise (at 214) forming third interconnects - i.e., locally insulated interconnects - which, between the hardware interfaces of the die, are to be electrically insulated from any transmitter circuit or receiver circuit of the die. For example, after fabrication of the wafer, the two hardware interfaces are to extend in different respective horizontal planes, wherein the first interconnects, second interconnects, and third interconnects each extend through another horizontal plane which is between said horizontal planes. In one such embodiment, the first interconnects, second interconnects, and third interconnects are arranged in this other plane such that — along a direction which is orthogonal to a line in the plane — the first interconnects and the second interconnects are in an alternating arrangement with the third interconnects.

Furthermore, along the direction, the first interconnects are successively arranged to correspond to successively greater levels of bit significance - e.g., wherein, similarly, the second interconnects are successively arranged to correspond to successively greater levels of bit significance.

In various embodiments, the first interconnects form first swizzle circuits and the second interconnects form second swizzle circuits - e.g., wherein an arrangement of the first, second, and third interconnects relative to each other at a first one of the hardware interfaces is different than an arrangement of the first, second, and third interconnects interconnects relative to each other at a second one of the hardware interfaces. For example, some or all such swizzle circuits are formed in a FEOL — or, alternatively, in a BEOL — of the wafer. In an alternative embodiment, an arrangement of the first, second, and third interconnects relative to each other at the same at each of the two hardware interfaces.

In some embodiments, the first circuits (and/or the second circuits) each comprise a respective transmit driver circuit or, for example, each comprise a respective receiver circuit. For example, in one such embodiment, the first circuits (and/or the second circuits) are each to communicate a respective data bit via a corresponding channel. In another embodiment, the first circuits (and/or the second circuits) are each to instead communicate a respective address bit.

Although some embodiments are not limited in this regard, method 200 additionally or alternatively comprises one or more operations to couple and/or otherwise use an IC die, formed from the wafer processed by operations 205, with one or more similar IC dies. In one such embodiment, method 200 comprises (at 216) coupling the die to another die via one of the hardware interfaces - e.g., wherein such coupling is with a face-to-face configuration, a face-to-back configuration, or a back-to-back configuration of said dies. For example, the coupling at 216 is performed with flip-chip coupling, hybrid bonding and/or other suitable techniques. Additionally or alternatively, method 200 comprises (at 218) communicating data between the dies via the one of the hardware interfaces - e.g., while a die stack comprising the IC die formed by operations 205 is coupled to a printed circuit board or other suitable substrate.

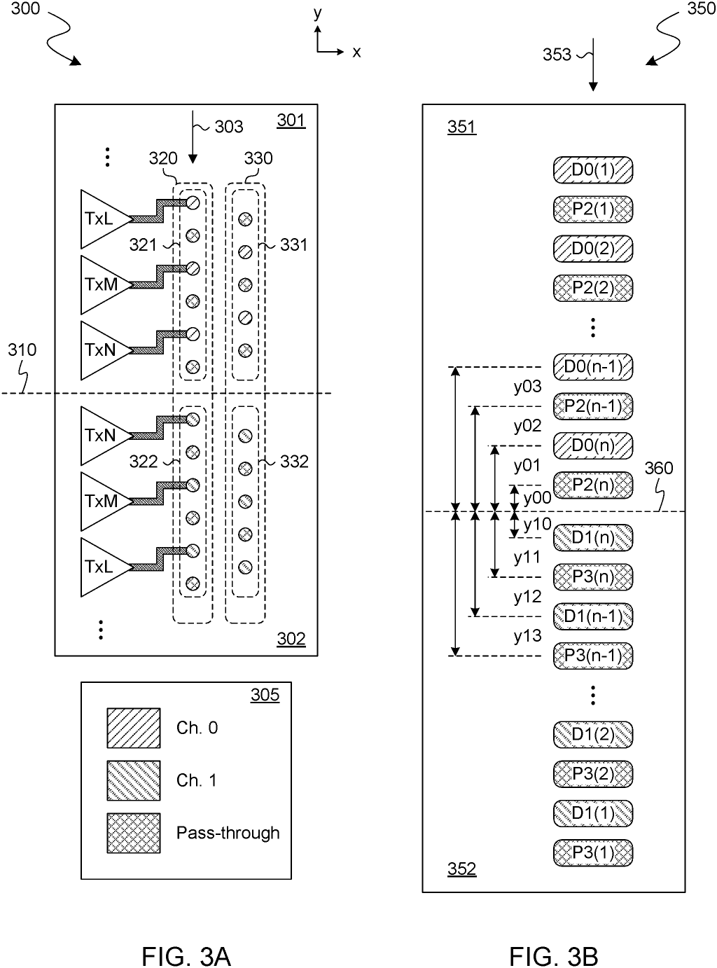

FIG. 3A shows features of a die 300 which comprises an arrangement of interconnect structures according to an embodiment. Die 300 illustrates one example of an embodiment wherein interconnect structures are arranged to facilitate stacking with one or more other dies -e.g., according to any of various possible stack configurations. In various embodiments, die 300 provides functionality such as that of one of IC dies 110, 120, 130 - e.g., wherein one or more operations of method 200 are performed to provide structures of die 300.

As shown in FIG. 3A, die 300 comprises first circuits - represented by the illustrative transmit driver circuits TxN, TxM, TxL, etc. in a region 301 of the x-y plane shown - which are to variously participate in a communication of first bits in a first channel (Ch. 0). Die 300 further comprises second circuits - represented by other transmit driver circuits TxN, TxM, TxL, etc. in another region 302 of the x-y plane - which are to variously participate in a communication of second bits in a second channel (Ch. 1). A straight line 310 in the x-y plane illustrates a delineation between regions 301, 302.

In some embodiments, die 300 further comprises multiple interconnects 320 which each extend through the x-y plane - e.g., wherein interconnects 320 each extend vertically from the plane to both of two hardware interfaces (not shown) which are on opposite respective surfaces of die 300. As indicated by legend 305, interconnects 320 comprise first interconnects which include both second interconnects in region 301, and third interconnects in region 302 -e.g., wherein the second interconnects and the third interconnects are on opposite sides of line 310. The second interconnects are each coupled to a different respective one of the first circuits, and (for example) are to communicate respective data bits — or alternatively, respective address bits — in the first channel. Similarly, the third interconnects are each coupled to a different respective one of the second circuits, and (for example) are to communicate respective data bits—or alternatively, respective address bits— in the second channel.

In various embodiments, the interconnects 320 further comprise fourth interconnects which are each a locally insulated, pass-through interconnect that, within die 300, is electrically insulated from any driver circuit (and any receiver circuit) of die 300. In one such embodiment, in the x-y plane shown (and also, along a line of direction 303 which is orthogonal to line 310), the first interconnects are in an alternating arrangement with the fourth interconnects.

Furthermore, in the x-y plane shown (and along the line of direction 303) the second interconnects are successively arranged in region 301 to correspond to successively greater levels of bit significance. For example, a bit to be communicated with the circuit TxL in region 301 is of a bit significance which is less than that of a bit to be communicated with the circuit TxM in region 301, which ― in turn ― is of a bit significance which is less than that of a bit to be communicated with the circuit TxN in region 301.

Further still, in the x-y plane shown (and along the line of direction 303), the third interconnects are successively arranged in region 302 to correspond to successively lesser levels of bit significance. For example, a bit to be communicated with the circuit TxN in region 302 is of a bit significance which is greater than that of a bit to be communicated with the circuit TxM in region 302, which ― in turn ― is of a bit significance which is greater than that of a bit to be communicated with the circuit TxL in region 302

In the example embodiment shown, interconnects 320 are substantially aligned with each other along the y-axis dimension, although some embodiments are not limited in this regard. In one such embodiment, die 300 further comprises another plurality of similarly aligned interconnects 330 - e.g., wherein various ones of interconnects 320 are to communicate respective data bits, and various ones of interconnects 330 are to communicate address bits corresponding to said data bits.

By way of illustration and not limitation, in some embodiments, interconnects 330 comprise interconnects 331 in region 301 - e.g., wherein, in the x-y plane, interconnects 331 comprise an alternating arrangement of fifth interconnects and sixth interconnects along direction 303. Such fifth interconnects are each coupled (for example) to a different respective transmitter circuit ― or alternatively, each to a respective receiver circuit ― of die 300. By contrast, the sixth interconnects which are local insulated, pass-through interconnects.

Alternatively or in addition, interconnects 330 comprise other interconnects 332 in region 302 - e.g., wherein interconnects 332 comprise an alternating arrangement of seventh interconnects and eighth interconnects along direction 303. The seventh interconnects are coupled each to a different respective transmitter circuit (or alternatively, each to a respective receiver circuit) of die 300 - e.g., wherein eighth interconnects which are local insulated, pass-through interconnects.

FIG. 3B shows an arrangement 350 of interconnect structures each in a plane of an IC die according to an embodiment. Arrangement 350 is provided with interconnects of die 300, for example. As shown in FIG. 3B, arrangement 350 is in a horizontal (x-y) plane of the IC die ― e.g., wherein some interconnects of the IC die variously extend through a region 351 of the plane, and other interconnects of the IC die variously extend through another region 352 of the plane. A line 360 in the x-y plane shown illustrates a delineation between regions 351, 352.

For example, region 351 comprises respective portions of interconnects D0(1), D0(2),..., D0(n-1), D0(n) which are each coupled to a different respective transmitter circuit (or alternatively, each to a different respective receiver circuit) of the IC die. Region 351 further comprises respective portions of pass-through interconnects P2(1), P2(2),..., P2(n-1), P2(n) of the IC die. In one such embodiment, region 352 comprises respective portions of interconnects D1(1), D1(2),..., D1(n-1), D1(n) which are each coupled to a different respective transmitter circuit (or alternatively, each to a different respective receiver circuit) of the IC die. Furthermore, region 352 comprises respective portions of pass-through interconnects P3(1), P3(2),..., P3(n-1), P3(n) of the IC die.

With reference to the labeling of a given interconnect in arrangement 350, the notation “D” indicates that the interconnect in question is coupled to communicate a data bit (or alternatively, an address bit) with a respective circuit of the IC die. The alternative notation “P” indicates that the interconnect in question is a pass-through interconnect which is locally insulated from any transmit driver circuit or receiver circuit of the IC die. Furthermore, the numerical notation - e.g., “0” in “D0,” “1” in “D1,” or the like - indicates a channel for which the interconnect in question is to communicate a respective bit.

Further still, the parenthetical notation - e.g., one of “(n),” “(n-1),”... “(2),” or “(1)” -indicates a level of significance of a bit which is to be communicated with the interconnect in question. For example, “1” indicates a least significant bit of multiple bits - e.g., wherein “2” indicates a second least significant bit, “(n-1)” indicates a second most significant bit, and “(n)” indicates a most significant bit. In one such embodiment, the multiple bits are contiguous with each other in a byte, a word, a double word, a long word, or the like. In the case of a pass-through interconnect, such a parenthetical notation indicates a level of significance of a bit that is to be communicated with a transmitter circuit (or alternatively, a receiver circuit) of another IC die that is to be coupled to the IC die which comprises arrangement 350.

In the example embodiment shown, individual interconnects - in a sequence of the pass-through interconnects P2(1), P2(2),..., P2(n-1), P2(n), P3(n), P3(n-1),..., P3(2), P3(1) ― alternate with individual interconnects in another sequence D0(1),D0(2),..., D0(n-1), D0(n), D1(n), D1(n-1),..., D1(2), D1(1) of the other interconnects (i.e., wherein the sequences are each along a line of direction 353 which is orthogonal to line 360).

Furthermore, for a given communication channel, interconnects are variously located in proximity to line 360 according to the respective levels of bit significance to which the interconnects correspond. For example, the respective distances of the interconnects D0(1), D0(2),..., D0(n-1), D0(n) from line are negatively related to the respective levels of bit significance to which the interconnects variously correspond. By way of illustration and not limitation, interconnect D0(n), as compared to interconnect D0(n-1), is closer to line 360 ― wherein distance y01 is less than distance y03 - and corresponds to a greater level of bit significance. Furthermore, interconnect P2(n), as compared to interconnect P2(n-1), is closer to line 360 ― wherein distance y00 is less than distance y02 - and corresponds to a greater level of bit significance. Further still, interconnect D1(n), as compared to interconnect D1(n-1), is closer to line 360 ― wherein distance y10 is less than distance y12 ― and corresponds to a greater level of bit significance. Further still, interconnect P3(n), as compared to interconnect P3(n-1), is closer to line 360 ― wherein distance y11 is less than distance y13 - and corresponds to a greater level of bit significance. In some embodiments, distance y00 is substantially equal to distance y10, distance y01 is substantially equal to distance y11, distance y02 is substantially equal to distance y12, etc. (although other embodiments are not limited in this regard).

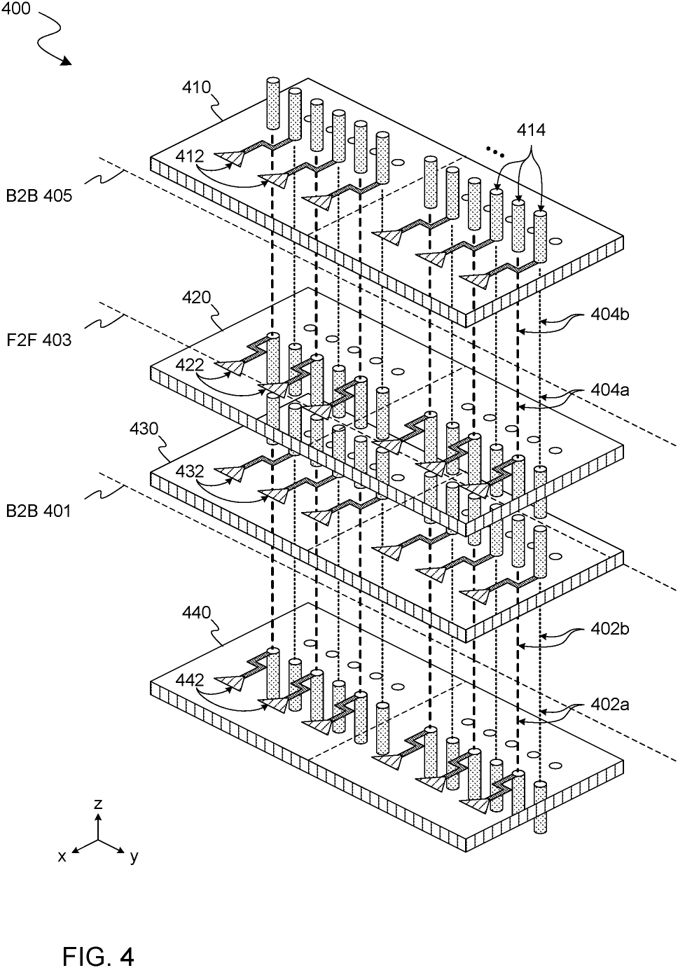

FIG. 4 illustrates features of a device 400 comprising an IC die stack according to an embodiment. Device 400 illustrates one example of an embodiment wherein IC dies are variously stacked in an arrangement of alternating configurations comprising one or more face-to-face configurations and one or more back-to-back configurations. In various embodiments, the IC die stack of device 400 comprises one or more IC dies that each comprise respective interconnects which have features of arrangement 350 (for example) - e.g., wherein one or more operations of method 200 comprise providing and/or using structures of device 400.

As shown in FIG. 4, device 400 comprises dies 410, 420, 430, 440 which are coupled to each other in a stacked arrangement. In the example embodiment shown, dies 410, 430 are each in a “face down” orientation in the stack, wherein, for each of dies 410, 430, the FEOL of the die is positioned under the BEOL of the die. By contrast, dies 420, 440 are each in a “face up” orientation in the stack, wherein, for each of dies 420, 440, the FEOL of the die is positioned above the BEOL of the die.

Accordingly, respective hardware interfaces of dies 410, 420 are coupled to each other in a face-to-face configuration represented by the B2B interface 405 shown. Furthermore, respective hardware interfaces of dies 420, 430 are coupled to each other in a back-to-back configuration represented by the B2B interface 403 shown. Further still, respective hardware interfaces of dies 430, 440 are coupled to each other in a face-to-face configuration represented by the B2B interface 401 shown.

As illustrated herein, a given one of dies 410, 420, 430, 440 has an arrangement of interconnects which accommodates incorporation of the die into one or more other types of die stacks (e.g., in addition to the die stack of device 400). For example, in various embodiments, some or all of dies 410, 420, 430, 440 each provide functionality such as that of die 300, or of one of dies 110, 120, 130 - e.g., wherein each such die comprises respective interconnects which are configured, relative to each other, to provide arrangement 350. For example, multiple interconnects of die 410 comprise respective structures which variously extend through a FEOL, an active layer, and a BEOL of die 410. By way of illustration and not limitation, two of the multiple interconnects of die 410 each comprise both a respective one of via structures 414 which extend through a FEOL of die 410, and a respective one of interconnect structures 404b (represented by dashed lines) which extend through the BEOL of die 410. For example, the multiple interconnects of die 410 comprise through-silicon vias (TSVs), in an embodiment.

Similarly, multiple interconnects of die 420 comprise respective structures which extend through a FEOL, and active layer, and a BEOL of die 420 - e.g., wherein such multiple interconnects of die 420 comprise interconnect structures 404a which extend through the BEOL of die 410. These respective multiple interconnects of dies 410, 420 are coupled to each other via B2B interface 405 - e.g., wherein interconnect structures 404a are coupled each to a respective one of interconnect structures 404b.

Furthermore, multiple interconnects of die 430 similarly extend each through a FEOL, and active layer, and a BEOL of die 430 - e.g., wherein interconnect structures in the respective FEOLs of dies 420, 430 are coupled to each other via F2F interface 403. Further still, multiple interconnects of die 440 similarly extend each through a FEOL, and active layer, and a BEOL of die 440. The respective multiple interconnects of dies 430, 440 are coupled to each other via B2B interface 401 - e.g., wherein interconnect structures 402b in the BEOL of die 430 are coupled each to a respective one of interconnect structures 402a in a BEOL of die 440.

In various embodiments, the multiple interconnects of die 410 are coupled each to a respective one of circuits 412 of die 410 - e.g., wherein the multiple interconnects of die 420 are coupled each to a respective one of circuits 422 of die 420. Similarly, the multiple interconnects of die 430 are coupled each to a respective one of circuits 432 of die 430 - e.g., wherein the multiple interconnects of die 440 are coupled each to a respective one of circuits 442 of die 440. In one such embodiment, circuits 412 are each a respective transmitter circuit (or, in an alternative embodiment, are each a respective receiver circuit) - e.g., wherein circuits 422 are each a respective transmitter circuit or, alternatively, are each a respective receiver circuit. Similarly, circuits 432 are each a respective transmitter circuit (or, in an alternative embodiment, are each a respective receiver circuit) - e.g., wherein circuits 442 which are each a respective transmitter circuit or, alternatively, are each a respective receiver circuit.

In an embodiment, the multiple interconnects of die 420 have an arrangement, relative to each other, which is the same in a horizontal (x-y) plane proximate to B2B interface 405, as it is in another horizontal plane proximate to F2F interface 403 - e.g., wherein the arrangement is that of arrangement 350. Similarly, the multiple interconnects of die 430 has such an arrangement relative to each other, where said arrangement is the same in a horizontal plane proximate to F2F interface 403, as it is in another horizontal plane proximate to B2B interface 401. Similarly, the multiple interconnects of die 440 have an arrangement relative to each other, wherein said arrangement is the same in a horizontal plane proximate to B2B interface 401, as it is in another horizontal plane proximate to another interface (not shown) by which die 440 is to be coupled to another die, a circuit board and/or other such structure. In some embodiments, the multiple interconnects of die 410 have such an arrangement relative to each other, wherein the arrangement is the same in a horizontal plane proximate to B2B interface 405, as it is in another horizontal plane proximate to another interface (not shown) on the backside of die 410. In other embodiments, die 410 omits backside via structures 414 - e.g., wherein die 410 is top die of the stack, and wherein the multiple interconnects extend to (but not through) an active layer of die 410.

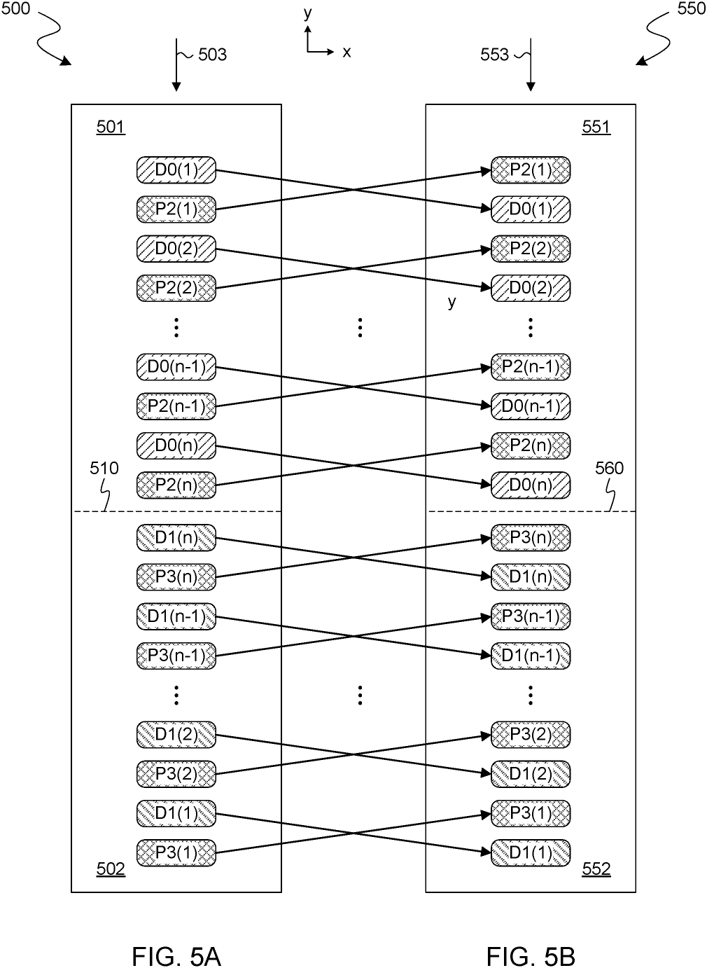

FIGS. 5A, 5B shows respective arrangements 500, 550 of interconnect structures each in a respective plane at an IC die according to an embodiment. Arrangements 500, 550 illustrate structures of an IC die which includes swizzle circuit structures. In various embodiments, interconnects such as those having arrangements 500, 550 are provided, for example, with one of IC dies 110, 120, 130 - e.g., wherein the interconnects are formed with operations of method 200.

As shown in FIG. 5A, arrangement 500 is in a first horizontal (x-y) plane of an IC die - e.g., wherein some interconnects of the IC die variously extend through a region 501 of the first plane, and other interconnects of the IC die variously extend through another region 502 of the first plane. A line 510 in the x-y plane shown illustrates a delineation between regions 501, 502. For example, region 501 comprises respective portions of interconnects D0(1),D0(2),..., D0(n-1), D0(n) which are each coupled to a different respective transmitter circuit (or each to a different respective receiver circuit) of the IC die. Region 501 further comprises respective portions of pass-through interconnects P2(1), P2(2),..., P2(n-1), P2(n) of the IC die. In one such embodiment, region 502 comprises respective portions of interconnects D1(1), D1(2),..., D1(n-1), D1(n) which are each coupled to a different respective transmitter circuit (or each to a different respective receiver circuit) of the IC die. Furthermore, region 502 comprises respective portions of pass-through interconnects P3(1), P3(2),..., P3(n-1), P3(n) of the IC die. In the example embodiment shown, individual interconnects - in a sequence of the pass-through interconnects P2(1), P2(2),..., P2(n-1), P2(n), P3(n), P3(n-1),..., P3(2), P3(1) ― alternate with individual interconnects in another sequence D0(1),D0(2),..., D0(n-1), D0(n), D1(n), D1(n-1),..., D1(2), D1(1) of the other interconnects (i.e., wherein the sequences are each along a line of direction 503 which is orthogonal to line 560).

As shown in FIG. 5B, arrangement 550 is in a second horizontal plane of the IC die which comprises arrangement 500 - e.g., wherein some interconnects of the IC die variously extend through a region 551 of the second plane, and other interconnects of the IC die variously extend through another region 552 of the second plane. For example, region 551 comprises respective portions of interconnects D0(1),D0(2),..., D0(n-1), D0(n), as well as respective portions of pass-through interconnects P2(1), P2(2),..., P2(n-1), P2(n) of the IC die. Furthermore, region 552 comprises respective portions of interconnects D1(1), D1(2),..., D1(n-1), D1(n), as well as respective portions of pass-through interconnects P3(1), P3(2),..., P3(n-1), P3(n) of the IC die. A line 560 in the x-y plane shown illustrates a delineation between regions 551, 552.

In an embodiment, differences between arrangements 500, 550 are provided with swizzle circuits of the IC die - e.g., wherein a BEOL (or alternatively, a FEOL) of the IC die comprises some or all such swizzle circuits. For example, interconnects D0(1),D0(2),..., D0(n-1), D0(n) are variously shifted - relative to interconnects P2(1), P2(2),..., P2(n-1), P2(n) - along a line of direction 553. Furthermore, interconnects D1(1), D1(2),..., D1(n-1), D1(n) are variously shifted - relative to interconnects P3(1), P3(2),..., P3(n-1), P3(n) - along the line of direction 553.

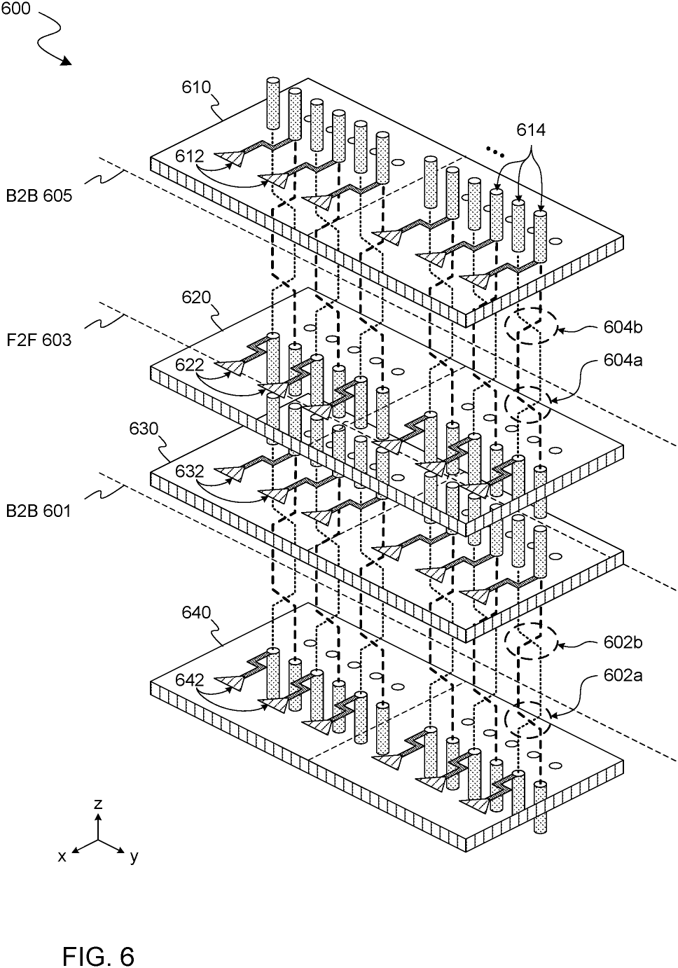

FIG. 6 illustrates features of a device 600 comprising an IC die stack according to an embodiment. Device 600 illustrates one example of an embodiment wherein IC dies - each comprising respective swizzle circuit structures ― are variously stacked in an arrangement of alternating configurations comprising one or more face-to-face configurations and one or more back-to-back configurations. In various embodiments, device 600 comprises IC dies that each comprise respective interconnects which have features of arrangement 500 and arrangement 550 (for example) - e.g., wherein one or more such IC dies are fabricated according to operations of method 200.

As shown in FIG. 6, device 600 comprises dies 610, 620, 630, 640 which are coupled to each other in a stacked arrangement. In the example embodiment shown, dies 610, 630 are each in a face down orientation in the stack, and dies 620, 640 are each in a face up orientation. Accordingly, dies 610, 620 are coupled to each other in a face-to-face configuration represented by the B2B interface 605 shown. Furthermore, dies 620, 630 are coupled to each other in a back-to-back configuration represented by the F2F interface 603 shown. Further still, dies 630, 640 are coupled to each other in a face-to-face configuration represented by the B2B interface 601 shown

Some or all of dies 610, 620, 630, 640 each provide functionality such as that of die 300, or of one of dies 110, 120, 130 - e.g., wherein each such die comprises respective interconnects which are configured, relative to each other, to provide arrangement 350. For example, multiple interconnects of die 610 comprise respective structures which extend through a FEOL, an active layer, and a BEOL of die 610.

As illustrated herein, a given one of dies 610, 620, 630, 640 has an arrangement of interconnects which accommodates incorporation of the die into one or more other types of die stacks (e.g., in addition to the die stack of device 600). For example, in the illustrative embodiment shown, two of the multiple interconnects of die 610 comprise respective ones of via structures 614 which extend through a FEOL of die 610, and further comprise respective BEOL interconnect structures which form a swizzle circuit 604b. Similarly, multiple interconnects of die 620 comprise respective structures which extend through a FEOL, and active layer, and a BEOL of die 620 - e.g., wherein such multiple interconnects of die 620 form a swizzle circuit 604a in the BEOL of die 610. These respective multiple interconnects of dies 610, 620 are coupled to each other via B2B interface 605 - e.g., wherein swizzle circuits 604a, 604b are coupled to each other via B2B interface 605.

Furthermore, multiple interconnects of die 630 similarly extend each through a FEOL, and active layer, and a BEOL of die 630 – e.g., wherein interconnect structures in respective FEOLs of dies 620, 630 are coupled to each other via F2F interface 603. Further still, multiple interconnects of die 640 similarly extend each through a FEOL, and active layer, and a BEOL of die 640. These respective multiple interconnects of dies 630, 640 are coupled to each other via B2B interface 601 - e.g., wherein a swizzle circuit 602b in the BEOL of die 630 is coupled to another swizzle circuit 602a in a BEOL of die 640.

In an embodiment, the multiple interconnects of die 610 are coupled each to a different respective one of circuits 612 of die 610 – e.g., wherein the multiple interconnects of die 620 are coupled each to a different respective one of circuits 622 of die 620. Furthermore, the multiple interconnects of die 630 are coupled each to a different respective one of circuits 632 of die 630 – e.g., wherein the multiple interconnects of die 640 are coupled each to a different respective one of circuits 642 of die 640. For example, some or all of circuits 612, 622, 632, 642 have features of circuits 412, 422, 432, 442

In an embodiment, an arrangement of the multiple interconnects of die 620, the arrangement in a horizontal (x-y) plane proximate to B2B interface 605, is different than that of the same multiple interconnects in another horizontal plane proximate to F2F interface 603 -e.g., wherein swizzle circuits of die 620 (comprising swizzle circuit 604a) provide a swizzling between arrangements 500, 550 (for example). Similarly, swizzle circuits of die 630 (comprising swizzle circuit 602b) provide swizzling whereby an arrangement of the multiple interconnects of die 630 – the arrangement in a horizontal plane proximate to F2F interface 603 ― is different than that of the same multiple interconnects in another horizontal plane proximate to B2B interface 601.

Similarly, swizzle circuits of die 640 (comprising swizzle circuit 602a) provide swizzling whereby an arrangement of the multiple interconnects of die 640 ― the arrangement in a horizontal plane proximate to B2B interface 601 ― is different than that of the same multiple interconnects in another horizontal plane proximate to another interface (not shown) by which die 640 is to be coupled to another die, a circuit board and/or other such structure. In some embodiments, swizzle circuits of die 610 (comprising swizzle circuit 604b) provide swizzling whereby an arrangement of the multiple interconnects of die 610 ― the arrangement in a horizontal plane proximate to B2B interface 605 ― is different than that of the same multiple interconnects in another horizontal plane proximate to the FEOL of die 610. In other embodiments, die 610 omits backside via structures 614 - e.g., wherein die 610 is top die of the stack, and wherein the multiple interconnects extend to (but not through) an active layer of die 610.

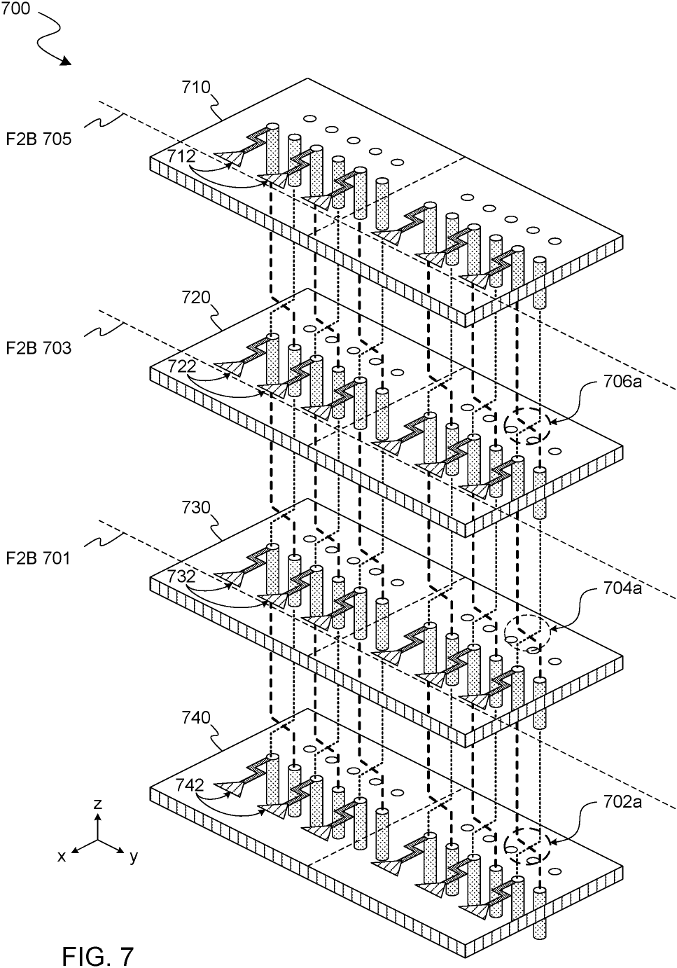

FIG. 7 illustrates features of a device 700 comprising an IC die stack according to another embodiment. Device 700 illustrates one example of an embodiment wherein IC dies ― comprising respective swizzle circuit structures ― are variously stacked in an arrangement of successive face-to-back configurations. In various embodiments, device 700 comprises IC dies that each comprise respective interconnects which have features of arrangement 350 (for example) - e.g., wherein such IC dies variously provide swizzling between arrangements 500, 550.

As shown in FIG. 7, device 700 comprises dies 710, 720, 730, 740 which are coupled to each other in a stacked arrangement. In the example embodiment shown, each of dies 710, 720, 730, 740 is in a face up orientation. Accordingly, dies 710, 720 are coupled to each other in a face-to-back configuration represented by the F2B interface 705 shown. Furthermore, dies 720, 730 are coupled to each other in a face-to-back configuration represented by the F2B interface 703 shown. Further still, dies 730, 740 are coupled to each other in a face-to-back configuration represented by the F2B interface 701 shown.

Dies 710, 720, 730, 740 each comprise structures of a respective one of dies 610, 620, 630, 640 - e.g., wherein, for each such die, the die comprises multiple interconnects which are configured to provide two different arrangements, relative to each other, at respective horizontal (x-y) planes in the die. In one such embodiment, multiple interconnects of a given one of dies 710, 720, 730, 740 form swizzle structures which facilitate a swizzling between two arrangements, such as arrangements 500, 550 (for example). By way of illustration and not limitation, interconnect structures in a BEOL of die 740 form a swizzle circuit 702a - e.g., wherein interconnect structures in a BEOL of die 730 form a swizzle circuit 704a, and wherein interconnect structures in a BEOL of die 720 form a swizzle circuit 706a.

In the example embodiment shown, multiple interconnects of die 710 are coupled to circuits 712 - e.g., wherein the multiple interconnects of die 720 are coupled to circuits 722. Furthermore, the multiple interconnects of die 730 are coupled to circuits 732 - e.g., wherein the multiple interconnects of die 740 are coupled to circuits 742. In one example embodiment, circuits 712, 722, 732, 742 correspond functionally to circuits 612, 622, 632, 642.

As illustrated herein, a given one of dies 710, 720, 730, 740 has an arrangement of interconnects which accommodates incorporation of the die into one or more other types of die stacks (e.g., in addition to the die stack of device 700). By way of illustration and not limitation, a top half of the metal stack in device 700, in an alternative embodiment, is replaced with a top half of the metal stack in device 400 - e.g., wherein dies 710, 720 (each in a face up orientation) are replaced with dies 410, 420 (in a face down orientation and a face up orientation, respectively). Any of various additional or alternative types of die stacking are provided, in some embodiments.

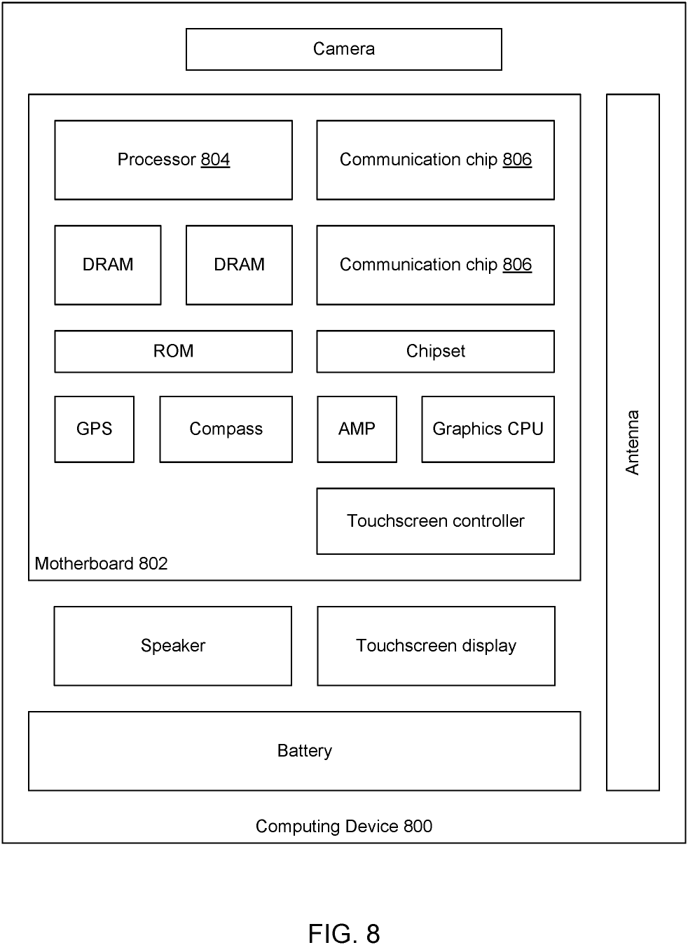

FIG. 8 illustrates a computing device 800 in accordance with one embodiment. The computing device 800 houses a board 802. The board 802 may include a number of components, including but not limited to a processor 804 and at least one communication chip 806. The processor 804 is physically and electrically coupled to the board 802. In some implementations the at least one communication chip 806 is also physically and electrically coupled to the board 802. In further implementations, the communication chip 806 is part of the processor 804.

Depending on its applications, computing device 800 may include other components that may or may not be physically and electrically coupled to the board 802. These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth). In some embodiments, DRAM and/or one or more memory resources of computing device 800 are provided at least in part with a IC die stack comprising one or more memory dies having features which are described herein.

The communication chip 806 enables wireless communications for the transfer of data to and from the computing device 800. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 806 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 800 may include a plurality of communication chips 806. For instance, a first communication chip 806 may be dedicated to shorter range wireless communications such as Wi-Fi and Bluetooth and a second communication chip 806 may be dedicated to longer range wireless communications such as GPS, EDGE, GPRS, CDMA, WiMAX, LTE, Ev-DO, and others.

The processor 804 of the computing device 800 includes an integrated circuit die packaged within the processor 804. The term “processor” may refer to any device or portion of a device that processes electronic data from registers and/or memory to transform that electronic data into other electronic data that may be stored in registers and/or memory. The communication chip 806 also includes an integrated circuit die packaged within the communication chip 806.

In various implementations, the computing device 800 may be a laptop, a netbook, a notebook, an ultrabook, a smartphone, a tablet, a personal digital assistant (PDA), an ultra mobile PC, a mobile phone, a desktop computer, a server, a printer, a scanner, a monitor, a set-top box, an entertainment control unit, a digital camera, a portable music player, or a digital video recorder. In further implementations, the computing device 800 may be any other electronic device that processes data.

Some embodiments may be provided as a computer program product, or software, that may include a machine-readable medium having stored thereon instructions, which may be used to program a computer system (or other electronic devices) to perform a process according to an embodiment. A machine-readable medium includes any mechanism for storing or transmitting information in a form readable by a machine (e.g., a computer). For example, a machine-readable (e.g., computer-readable) medium includes a machine (e.g., a computer) readable storage medium (e.g., read only memory (“ROM”), random access memory (“RAM”), magnetic disk storage media, optical storage media, flash memory devices, etc.), a machine (e.g., computer) readable transmission medium (electrical, optical, acoustical or other form of propagated signals (e.g., infrared signals, digital signals, etc.)), etc.

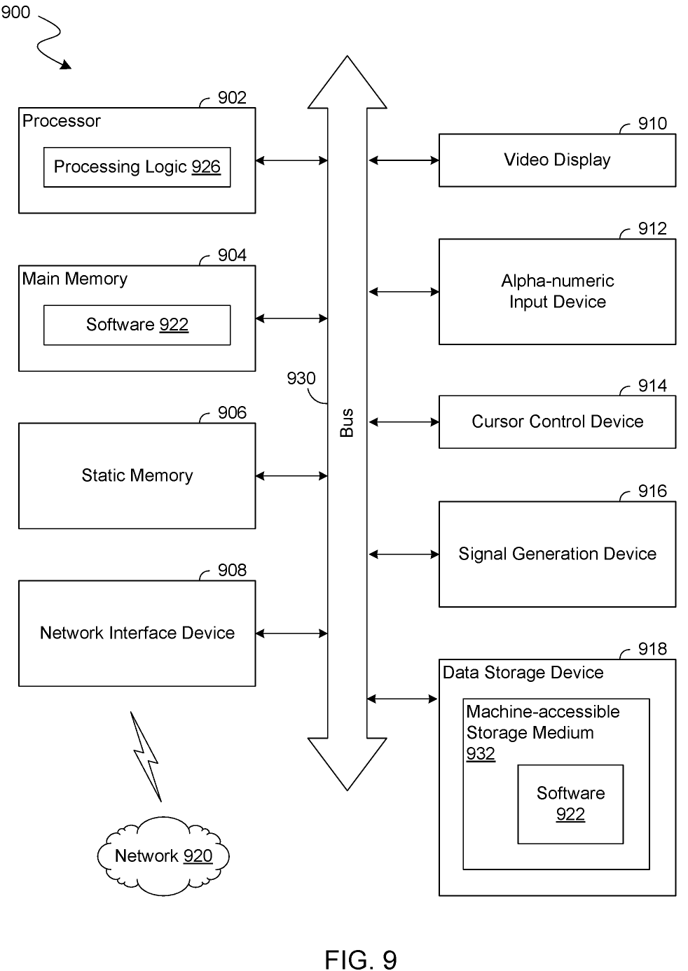

FIG. 9 illustrates a diagrammatic representation of a machine in the exemplary form of a computer system 900 within which a set of instructions, for causing the machine to perform any one or more of the methodologies described herein, may be executed. In alternative embodiments, the machine may be connected (e.g., networked) to other machines in a Local Area Network (LAN), an intranet, an extranet, or the Internet. The machine may operate in the capacity of a server or a client machine in a client-server network environment, or as a peer machine in a peer-to-peer (or distributed) network environment. The machine may be a personal computer (PC), a tablet PC, a set-top box (STB), a Personal Digital Assistant (PDA), a cellular telephone, a web appliance, a server, a network router, switch or bridge, or any machine capable of executing a set of instructions (sequential or otherwise) that specify actions to be taken by that machine. Further, while only a single machine is illustrated, the term “machine” shall also be taken to include any collection of machines (e.g., computers) that individually or jointly execute a set (or multiple sets) of instructions to perform any one or more of the methodologies described herein.

The exemplary computer system 900 includes a processor 902, a main memory 904 (e.g., read-only memory (ROM), flash memory, dynamic random access memory (DRAM) such as synchronous DRAM (SDRAM) or Rambus DRAM (RDRAM), etc.), a static memory 906 (e.g., flash memory, static random access memory (SRAM), etc.), and a secondary memory 918 (e.g., a data storage device), which communicate with each other via a bus 930. In some embodiments, one or more memory resources of computer system 900 - e.g., including main memory 904, static memory 906 or the like ― are provided at least in part with a IC die stack comprising one or more memory dies having features which are described herein.

Processor 902 represents one or more general-purpose processing devices such as a microprocessor, central processing unit, or the like. More particularly, the processor 902 may be a complex instruction set computing (CISC) microprocessor, reduced instruction set computing (RISC) microprocessor, very long instruction word (VLIW) microprocessor, processor implementing other instruction sets, or processors implementing a combination of instruction sets. Processor 902 may also be one or more special-purpose processing devices such as an application specific integrated circuit (ASIC), a field programmable gate array (FPGA), a digital signal processor (DSP), network processor, or the like. Processor 902 is configured to execute the processing logic 926 for performing the operations described herein.

The computer system 900 may further include a network interface device 908. The computer system 900 also may include a video display unit 910 (e.g., a liquid crystal display (LCD), a light emitting diode display (LED), or a cathode ray tube (CRT)), an alphanumeric input device 912 (e.g., a keyboard), a cursor control device 914 (e.g., a mouse), and a signal generation device 916 (e.g., a speaker).

The secondary memory 918 may include a machine-accessible storage medium (or more specifically a computer-readable storage medium) 932 on which is stored one or more sets of instructions (e.g., software 922) embodying any one or more of the methodologies or functions described herein. The software 922 may also reside, completely or at least partially, within the main memory 904 and/or within the processor 902 during execution thereof by the computer system 900, the main memory 904 and the processor 902 also constituting machine-readable storage media. The software 922 may further be transmitted or received over a network 920 via the network interface device 908.

While the machine-accessible storage medium 932 is shown in an exemplary embodiment to be a single medium, the term “machine-readable storage medium” should be taken to include a single medium or multiple media (e.g., a centralized or distributed database, and/or associated caches and servers) that store the one or more sets of instructions. The term “machine-readable storage medium” shall also be taken to include any medium that is capable of storing or encoding a set of instructions for execution by the machine and that cause the machine to perform any of one or more embodiments. The term “machine-readable storage medium” shall accordingly be taken to include, but not be limited to, solid-state memories, and optical and magnetic media.

Techniques and architectures for stacking IC dies are described herein. In the above description, for purposes of explanation, numerous specific details are set forth in order to provide a thorough understanding of certain embodiments. It will be apparent, however, to one skilled in the art that certain embodiments can be practiced without these specific details. In other instances, structures and devices are shown in block diagram form in order to avoid obscuring the description.

Reference in the specification to “one embodiment” or “an embodiment” means that a particular feature, structure, or characteristic described in connection with the embodiment is included in at least one embodiment of the invention. The appearances of the phrase “in one embodiment” in various places in the specification are not necessarily all referring to the same embodiment.

Some portions of the detailed description herein are presented in terms of algorithms and symbolic representations of operations on data bits within a computer memory. These algorithmic descriptions and representations are the means used by those skilled in the computing arts to most effectively convey the substance of their work to others skilled in the art. An algorithm is here, and generally, conceived to be a self-consistent sequence of steps leading to a desired result. The steps are those requiring physical manipulations of physical quantities. Usually, though not necessarily, these quantities take the form of electrical or magnetic signals capable of being stored, transferred, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. Unless specifically stated otherwise as apparent from the discussion herein, it is appreciated that throughout the description, discussions utilizing terms such as “processing” or “computing” or “calculating” or “determining” or “displaying” or the like, refer to the action and processes of a computer system, or similar electronic computing device, that manipulates and transforms data represented as physical (electronic) quantities within the computer system’s registers and memories into other data similarly represented as physical quantities within the computer system memories or registers or other such information storage, transmission or display devices.

Certain embodiments also relate to apparatus for performing the operations herein. This apparatus may be specially constructed for the required purposes, or it may comprise a general purpose computer selectively activated or reconfigured by a computer program stored in the computer. Such a computer program may be stored in a computer readable storage medium, such as, but is not limited to, any type of disk including floppy disks, optical disks, CD-ROMs, and magnetic-optical disks, read-only memories (ROMs), random access memories (RAMs) such as dynamic RAM (DRAM), EPROMs, EEPROMs, magnetic or optical cards, or any type of media suitable for storing electronic instructions, and coupled to a computer system bus.

The algorithms and displays presented herein are not inherently related to any particular computer or other apparatus. Various general purpose systems may be used with programs in accordance with the teachings herein, or it may prove convenient to construct more specialized apparatus to perform the required method steps. The required structure for a variety of these systems will appear from the description herein. In addition, certain embodiments are not described with reference to any particular programming language. It will be appreciated that a variety of programming languages may be used to implement the teachings of such embodiments as described herein.

In one or more first embodiments, an integrated circuit (IC) die comprises first circuits to participate in a first communication via first channel, second circuits to participate in a second communication via a second channel, and multiple interconnects which each extend through a plane and to hardware interfaces on opposite respective surfaces of the IC die, the multiple interconnects comprising first interconnects comprising second interconnects which are each coupled to a different respective one of the first circuits, and third interconnects which are each coupled to a different respective one of the second circuits, and fourth interconnects which, within the IC die, are each electrically insulated from any transmit driver circuit and from any receiver circuit of the IC die, wherein, in the plane and along a first direction orthogonal to a second line in the plane the first interconnects are in an alternating arrangement with the fourth interconnects, the second interconnects are successively arranged to correspond to successively greater levels of bit significance, and the third interconnects are successively arranged to correspond to successively lesser levels of bit significance, and the second interconnects and the third interconnects are on opposite sides of the second line.

In one or more second embodiments, further to the first embodiment, an arrangement of the multiple interconnects relative to each other in a first plane proximate to a first one of the hardware interfaces is the same as an arrangement of the multiple interconnects relative to each other in a second plane proximate to a second one of the hardware interfaces.

In one or more third embodiments, further to the first embodiment, the first interconnects comprise first swizzle circuit structures, and wherein the second interconnects comprise second swizzle circuit structures.

In one or more fourth embodiments, further to any of the first through third embodiments, the first circuits each comprise a respective transmit driver circuit, or each comprise a respective receiver circuit.

In one or more fifth embodiments, further to the fourth embodiment, the second circuits each comprise a respective transmit driver circuit, or each comprise a respective receiver circuit.

In one or more sixth embodiments, further to any of the first through third embodiments, each of the first circuits is to provide a respective data bit of the first communication, and wherein each of the second circuits is to provide a respective data bit of the second communication.

In one or more seventh embodiments, further to any of the first through third embodiments, each of the first circuits is to provide a respective address bit of the first communication, and wherein each of the second circuits is to provide a respective address bit of the second communication.

In one or more eighth embodiments, further to any of the first through third embodiments, the first interconnects and the fourth interconnects are substantially aligned with each other in the plane.

In one or more ninth embodiments, further to any of the first through third embodiments, the IC die further comprises fifth interconnects comprising sixth interconnects which are each coupled to a different respective one of the first circuits, and seventh interconnects which are each coupled to a different respective one of the second circuits, and eighth interconnects which, within the IC die, are each electrically insulated from any transmit driver circuit and from any receiver circuit of the IC die, wherein, in the plane and along a third direction orthogonal to the second line the fifth interconnects are in an alternating arrangement with the eighth interconnects, the sixth interconnects are successively arranged to correspond to successively greater levels of bit significance, and the seventh interconnects are successively arranged to correspond to successively lesser levels of bit significance, and the sixth interconnects and the seventh interconnects are on opposite sides of the second line.

In one or more tenth embodiments, a method for fabricating a wafer comprises forming multiple interconnects which each extend through a plane and to hardware interfaces on opposite respective surfaces of the wafer, comprising forming first interconnects comprising second interconnects which are each coupled to a different respective one of first circuits of the wafer, and third interconnects which are each coupled to a different respective one of second circuits of the wafer, and forming fourth interconnects which, within the wafer, are each electrically insulated from any transmit driver circuit and from any receiver circuit of the wafer, wherein, in the plane and along a first direction orthogonal to a second line in the plane the first interconnects are in an alternating arrangement with the fourth interconnects, the second interconnects are successively arranged to correspond to successively greater levels of bit significance, and the third interconnects are successively arranged to correspond to successively lesser levels of bit significance, and the second interconnects and the third interconnects are on opposite sides of the second line, and wherein the first circuits and the the second circuits are to participate, respectively, in a first communication via first channel, and a a second communication via a second channel.

In one or more eleventh embodiments, further to the tenth embodiment, an arrangement of the multiple interconnects relative to each other in a first plane proximate to a first one of the hardware interfaces is the same as an arrangement of the multiple interconnects relative to each other in a second plane proximate to a second one of the hardware interfaces.

In one or more twelfth embodiments, further to the tenth embodiment, the first interconnects comprise first swizzle circuit structures, and wherein the second interconnects comprise second swizzle circuit structures.

In one or more thirteenth embodiments, further to any of the tenth through twelfth embodiments, the first circuits each comprise a respective transmit driver circuit, or each comprise a respective receiver circuit.

In one or more fourteenth embodiments, further to the thirteenth embodiment, the second circuits each comprise a respective transmit driver circuit, or each comprise a respective receiver circuit.

In one or more fifteenth embodiments, further to any of the tenth through twelfth embodiments, each of the first circuits is to provide a respective data bit of the first communication, and wherein each of the second circuits is to provide a respective data bit of the second communication.

In one or more sixteenth embodiments, further to any of the tenth through twelfth embodiments, each of the first circuits is to provide a respective address bit of the first communication, and wherein each of the second circuits is to provide a respective address bit of the second communication.

In one or more seventeenth embodiments, further to any of the tenth through twelfth embodiments, the first interconnects and the fourth interconnects are substantially aligned with each other in the plane.

In one or more eighteenth embodiments, further to any of the tenth through twelfth embodiments, the method further comprises forming fifth interconnects comprising sixth interconnects which are each coupled to a different respective one of the first circuits, and seventh interconnects which are each coupled to a different respective one of the second circuits, and forming eighth interconnects which, within the wafer, are each electrically insulated from any transmit driver circuit and from any receiver circuit of the wafer, wherein, in the plane and along a third direction orthogonal to the second line the fifth interconnects are in an alternating arrangement with the eighth interconnects, the sixth interconnects are successively arranged to correspond to successively greater levels of bit significance, and the seventh interconnects are successively arranged to correspond to successively lesser levels of bit significance, and the sixth interconnects and the seventh interconnects are on opposite sides of the second line.

In one or more nineteenth embodiments, a system comprises a die stack comprising a memory die which comprises first circuits to participate in a first communication via first channel, second circuits to participate in a second communication via a second channel, and multiple interconnects which each extend through a plane and to hardware interfaces on opposite respective surfaces of the memory die, the multiple interconnects comprising first interconnects comprising second interconnects which are each coupled to a different respective one of the first circuits, and third interconnects which are each coupled to a different respective one of the second circuits, and fourth interconnects which, within the memory die, are each electrically insulated from any transmit driver circuit and from any receiver circuit of the memory die, and a display device coupled to the die stack, the display device to display an image based on one of the first communication or the second communication, wherein, in the plane and along a first direction orthogonal to a second line in the plane the first interconnects are in an alternating arrangement with the fourth interconnects, the second interconnects are successively arranged to correspond to successively greater levels of bit significance, and the third interconnects are successively arranged to correspond to successively lesser levels of bit significance, and the second interconnects and the third interconnects are on opposite sides of the second line.

In one or more twentieth embodiments, further to the nineteenth embodiment, an arrangement of the multiple interconnects relative to each other in a first plane proximate to a first one of the hardware interfaces is the same as an arrangement of the multiple interconnects relative to each other in a second plane proximate to a second one of the hardware interfaces.

In one or more twenty-first embodiments, further to the nineteenth embodiment, the first interconnects comprise first swizzle circuit structures, and wherein the second interconnects comprise second swizzle circuit structures.

In one or more twenty-second embodiments, further to any of the nineteenth through twenty-first embodiments, the first circuits each comprise a respective transmit driver circuit, or each comprise a respective receiver circuit.

In one or more twenty-third embodiments, further to the twenty-second embodiment, the second circuits each comprise a respective transmit driver circuit, or each comprise a respective receiver circuit.

In one or more twenty-fourth embodiments, further to any of the nineteenth through twenty-first embodiments, each of the first circuits is to provide a respective data bit of the first communication, and wherein each of the second circuits is to provide a respective data bit of the second communication.

In one or more twenty-fifth embodiments, further to any of the nineteenth through twenty-first embodiments, each of the first circuits is to provide a respective address bit of the first communication, and wherein each of the second circuits is to provide a respective address bit of the second communication.

In one or more twenty-sixth embodiments, further to any of the nineteenth through twenty-first embodiments, the first interconnects and the fourth interconnects are substantially aligned with each other in the plane.

In one or more twenty-seventh embodiments, further to any of the nineteenth through twenty-first embodiments, the memory die further comprises fifth interconnects comprising sixth interconnects which are each coupled to a different respective one of the first circuits, and seventh interconnects which are each coupled to a different respective one of the second circuits, and eighth interconnects which, within the IC die, are each electrically insulated from any transmit driver circuit and from any receiver circuit of the IC die, wherein, in the plane and along a third direction orthogonal to the second line the fifth interconnects are in an alternating arrangement with the eighth interconnects, the sixth interconnects are successively arranged to correspond to successively greater levels of bit significance, and the seventh interconnects are successively arranged to correspond to successively lesser levels of bit significance, and the sixth interconnects and the seventh interconnects are on opposite sides of the second line.

Besides what is described herein, various modifications may be made to the disclosed embodiments and implementations thereof without departing from their scope. Therefore, the illustrations and examples herein should be construed in an illustrative, and not a restrictive sense. The scope of the invention should be measured solely by reference to the claims that follow.

What is claimed is:

1. An integrated circuit (IC) die comprising:
first circuits to participate in a first communication via first channel;
second circuits to participate in a second communication via a second channel; and
multiple interconnects which each extend through a plane and to hardware interfaces on opposite respective surfaces of the IC die, the multiple interconnects comprising:
first interconnects comprising second interconnects which are each coupled to a different respective one of the first circuits, and third interconnects which are each coupled to a different respective one of the second circuits; and
fourth interconnects which, within the IC die, are each electrically insulated from any transmit driver circuit and from any receiver circuit of the IC die;
wherein, in the plane and along a first direction orthogonal to a second line in the plane:
the first interconnects are in an alternating arrangement with the fourth interconnects, the second interconnects are successively arranged to correspond to successively greater levels of bit significance, and the third interconnects are successively arranged to correspond to successively lesser levels of bit significance, and the second interconnects and the third interconnects are on opposite sides of the second line.

2. The IC die of claim 1, wherein an arrangement of the multiple interconnects relative to each other in a first plane proximate to a first one of the hardware interfaces is the same as an arrangement of the multiple interconnects relative to each other in a second plane proximate to a second one of the hardware interfaces.

3. The IC die of claim 1, wherein the first interconnects comprise first swizzle circuit structures, and wherein the second interconnects comprise second swizzle circuit structures.

4. The IC die of claim 1, wherein the first circuits each comprise a respective transmit driver circuit, or each comprise a respective receiver circuit.

5. The IC die of claim 4, wherein the second circuits each comprise a respective transmit driver circuit, or each comprise a respective receiver circuit.

6. The IC die of claim 1, wherein each of the first circuits is to provide a respective data bit of the first communication, and wherein each of the second circuits is to provide a respective data bit of the second communication.

7. The IC die of claim 1, wherein each of the first circuits is to provide a respective address bit of the first communication, and wherein each of the second circuits is to provide a respective address bit of the second communication.

8. The IC die of claim 1, wherein the first interconnects and the fourth interconnects are substantially aligned with each other in the plane.

9. The IC die of claim 1, further comprising:
fifth interconnects comprising sixth interconnects which are each coupled to a different respective one of the first circuits, and seventh interconnects which are each coupled to a different respective one of the second circuits; and
eighth interconnects which, within the IC die, are each electrically insulated from any transmit driver circuit and from any receiver circuit of the IC die;
wherein, in the plane and along a third direction orthogonal to the second line:
the fifth interconnects are in an alternating arrangement with the eighth interconnects, the sixth interconnects are successively arranged to correspond to successively greater levels of bit significance, and the seventh interconnects are successively arranged to correspond to successively lesser levels of bit significance, and the sixth interconnects and the seventh interconnects are on opposite sides of the second line.

10. A method for fabricating an integrated circuit (IC) die, the method comprising:
forming multiple interconnects which each extend through a plane and to hardware interfaces on opposite respective surfaces of the IC die, comprising:
forming first interconnects comprising second interconnects which are each coupled to a different respective one of first circuits of the IC die, and third interconnects which are each coupled to a different respective one of second circuits of the IC die; and
forming fourth interconnects which, within the IC die, are each electrically insulated from any transmit driver circuit and from any receiver circuit of the IC die;
wherein, in the plane and along a first direction orthogonal to a second line in the plane:
the first interconnects are in an alternating arrangement with the fourth interconnects, the second interconnects are successively arranged to correspond to successively greater levels of bit significance, and the third interconnects are successively arranged to correspond to successively lesser levels of bit significance, and the second interconnects and the third interconnects are on opposite sides of the second line; and
wherein the first circuits and the the second circuits are to participate, respectively, in a first communication via first channel, and a a second communication via a second channel.

11. The method of claim 10, wherein an arrangement of the multiple interconnects relative to each other in a first plane proximate to a first one of the hardware interfaces is the same as an arrangement of the multiple interconnects relative to each other in a second plane proximate to a second one of the hardware interfaces.

12. The method of claim 10, wherein the first interconnects comprise first swizzle circuit structures, and wherein the second interconnects comprise second swizzle circuit structures.

13. The method of claim 10, wherein the first circuits each comprise a respective transmit driver circuit, or each comprise a respective receiver circuit.

14. The method of claim 10, wherein each of the first circuits is to provide a respective data bit of the first communication, and wherein each of the second circuits is to provide a respective data bit of the second communication.

15. A system comprising:
a die stack comprising a memory die which comprises:
first circuits to participate in a first communication via first channel;
second circuits to participate in a second communication via a second channel; and
multiple interconnects which each extend through a plane and to hardware interfaces on opposite respective surfaces of the memory die, the multiple interconnects comprising:
first interconnects comprising second interconnects which are each coupled to a different respective one of the first circuits, and third interconnects which are each coupled to a different respective one of the second circuits; and
fourth interconnects which, within the memory die, are each electrically insulated from any transmit driver circuit and from any receiver circuit of the memory die; and
a display device coupled to the die stack, the display device to display an image based on one of the first communication or the second communication;
wherein, in the plane and along a first direction orthogonal to a second line in the plane:
the first interconnects are in an alternating arrangement with the fourth interconnects, the second interconnects are successively arranged to correspond to successively greater levels of bit significance, and the third interconnects are successively arranged to correspond to successively lesser levels of bit significance, and the second interconnects and the third interconnects are on opposite sides of the second line.

16. The system of claim 15, wherein an arrangement of the multiple interconnects relative to each other in a first plane proximate to a first one of the hardware interfaces is the same as an arrangement of the multiple interconnects relative to each other in a second plane proximate to a second one of the hardware interfaces.

17. The system of claim 15, wherein the first interconnects comprise first swizzle circuit structures, and wherein the second interconnects comprise second swizzle circuit structures.

18. The system of claim 15, wherein the first circuits each comprise a respective transmit driver circuit, or each comprise a respective receiver circuit.

19. The system of claim 18, wherein the second circuits each comprise a respective transmit driver circuit, or each comprise a respective receiver circuit.

20. The system of claim 15, wherein each of the first circuits is to provide a respective data bit of the first communication, and wherein each of the second circuits is to provide a respective data bit of the second communication.
